(19) United States
(12) Patent Application Publication
(10) Pub. No.: US 2024/0276641 A1
(43) Pub. Date: Aug. 15, 2024

(54) LIGHT-EMITTING DEVICE AND ELECTRICAL MODULE THEREOF

(71) Applicants: Lextar Electronics Corporation, Hsinchu City (TW); Lextar Electronics(Chuzhou) Corporation, Chuzhou City (CN)

(72) Inventors: Sheng-Ta WU, Hsinchu City (TW); Li Jin DENG, Hsinchu City (TW); Long CHANG, Hsinchu City (TW); Lei QIU, Hsinchu City (TW)

(21) Appl. No.: 18/435,062

(22) Filed: Feb. 7, 2024

(30) Foreign Application Priority Data
Feb. 14, 2023 (CN) 202320217369.2

(51) Int. Cl. H05K 1/11; H01L 23/544; H01L 25/075

(52) U.S. Cl. CPC H05K 1/111; H01L 23/544; H01L 25/0753; H01L 2223/54426; H05K 2201/09254; H05K 2201/10106

(57) ABSTRACT

An electrical module is provided. The electrical module includes a circuit board. The circuit board includes at least one bonding pad. The bonding pad includes a bonding line and a plurality of traces. The traces are connected to the bonding line. The traces are configured in a radial manner. The bonding line includes a first section and a second section. The first section is connected to the second section. The first section extends in a first direction. The second section extends in a second direction. The first direction is perpendicular to the second direction. An extending direction of at least one of the traces differs from the first direction and the second direction.

### CROSS REFERENCE TO RELATED APPLICATIONS

This Application claims priority of China Patent Application No. 2023202173692, filed Feb. 14, 2023, the entirety of which is incorporated by reference herein.

### BACKGROUND OF THE DISCLOSURE

### Field of the Disclosure

The present disclosure relates to a electrical module, and, in particular, to a light-emitting device with bonding pads.

### Description of the Related Art

As the technological requirements on displays of notebooks increase, these displays should not only be light and thin, but also be bright and clear. Therefore, the number of light-emitting diodes of the light-emitting device incorporated in the display is increased, and the mounting accuracy of the light-emitting diodes should be improved. Therefore, the requirements for linearity have increased accordingly. Linearity is the consistency of the distances between the mounted light-emitting diodes and the light-emitting surface of the display. Improved linearity brings better brightness and a more uniform picture quality, and reduces problems such as buds or bright spots. Because the light-emitting diodes are connected to the circuit board through bonding pads, when the design of traditional bonding pads are too simple, the requirements of linearity and sufficient resistance of thrust cannot be met.

### BRIEF SUMMARY OF THE DISCLOSURE

An embodiment of the present disclosure provides an electrical module. The electrical module includes a circuit board. The circuit board includes at least one bonding pad. The bonding pad includes a bonding line and a plurality of traces. The traces are connected to the bonding line. The traces are configured in a radial manner. The bonding line includes a first section and a second section. The first section is connected to the second section. The first section extends in a first direction. The second section extends in a second direction. The first direction is perpendicular to the second direction. The extending direction of at least one of the traces differs from the first direction and the second direction.

In the electrical module of the embodiment of the disclosure, dual designs such as bonding line and traces are adopted to meet the requirements of linearity and resistance of thrust. The first section of the bonding line is perpendicular to the second section thereof to improve alignment accuracy, and the traces can extend obliquely to resist thrusts in different directions. In one embodiment, the number of such traces can be up to 10 to provide sufficient resistance of thrust. Specifically, under the same size or smaller bonding pad, the bonding lines of the embodiments of the disclosure not only provide good linearity, but also provide better resistance of thrust.

### BRIEF DESCRIPTION OF THE DRAWINGS

The present disclosure can be more fully understood by reading the subsequent detailed description and examples with references made to the accompanying drawings, wherein:

FIG. 1 shows a light-emitting device of the embodiment of the disclosure; and

FIG. 2 shows the details of an electrical module in accordance with the embodiment of the disclosure.

### DETAILED DESCRIPTION OF THE DISCLOSURE

The following description is made for the purpose of illustrating the general principles of the disclosure and should not be taken in a limiting sense. The scope of the disclosure is best determined by reference to the appended claims.

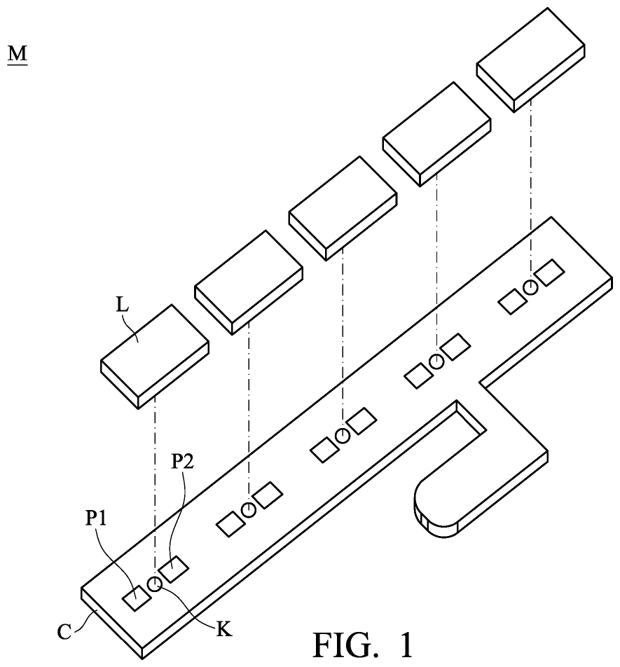

FIG. 1 shows a light-emitting device of the embodiment of the disclosure. With reference to FIG. 1, in one embodiment, a light-emitting device M is provided. The light-emitting device M includes a circuit board C and a light source element L. The circuit board C includes one pair of bonding pads (P1, P2). The light source element L is coupled to the pair of bonding pads (P1, P2). In one embodiment, the light source element L can be a light-emitting diode element. Above mentioned does not restrict the disclosure.

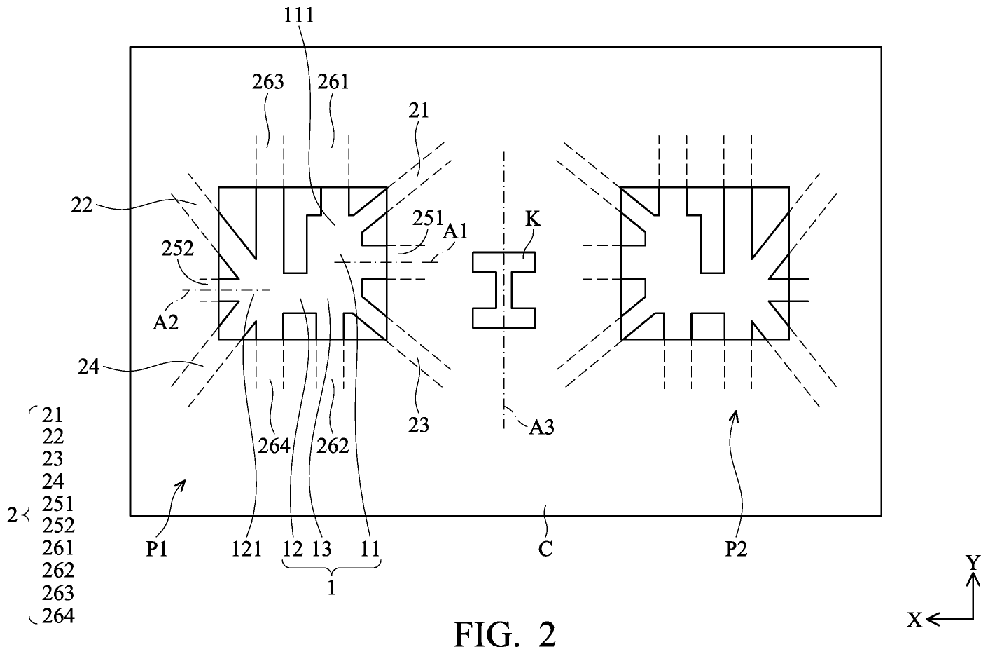

FIG. 2 shows the details of an electrical module of the embodiment of the disclosure. With reference to FIG. 2, the electrical module of the embodiment of the disclosure includes the circuit board C mentioned above. The circuit board C includes one bonding pad (for example, the bonding pad P1 or the bonding pad P2). The bonding pad P1 includes a bonding line 1 and a plurality of traces 2. The traces 2 are connected to the bonding line 1. The traces 2 are configured in a radial manner. The bonding line 1 includes a first section 11 and a second section 12. The first section 11 is connected to the second section 12. The first section 11 extends in a first direction Y. The second section 12 extends in a second direction X. The first direction Y is perpendicular to the second direction X. The extending direction of one of the traces 2 differs from the first direction Y and the second direction X.

With reference to FIG. 2, in one embodiment, the bonding line 1 is L-shaped. The first section 11 comprises a first end 111. The second section 12 comprises a second end 121. The first section 11 is connected to the second section 12 at a connection portion 13 of the bonding line 1.

With reference to FIG. 2, in one embodiment, the width of one portion of the bonding line 1 is greater than the width of each trace 2.

With reference to FIG. 2, in one embodiment, the traces 2 comprises a first inclined trace 21. The extending direction of the first inclined trace 21 is between the first direction Y and the second direction X (that means, the first inclined trace 21 is not parallel to the first direction Y, and not parallel to the second direction X). The first inclined trace 21 is connected to the first end 111.

With reference to FIG. 2, in one embodiment, the traces 2 comprises a second inclined trace 22. The extending direction of the second inclined trace 22 is between the first direction Y and the second direction X (that means, the second inclined trace 22 is not parallel to the first direction Y, and not parallel to the second direction X). The second inclined trace 22 is connected to the second end 121.

With reference to FIG. 2, in one embodiment, the traces 2 comprises a third inclined trace 23. The extending direction of the third inclined trace 23 is between the first direction and the second direction (that means, the third inclined trace 23 is not parallel to the first direction Y, and not parallel to the second direction X). The third inclined trace 23 is connected to the connection portion 13. The first inclined trace 21 is symmetric to the third inclined trace 23 relative to a first axis A1. The first axis A1 is parallel to the second direction X.

With reference to FIG. 2, in one embodiment, the traces 2 comprises a fourth inclined trace 24. The extending direction of the fourth inclined trace 24 is between the first direction and the second direction (that means, the fourth inclined trace 24 is not parallel to the first direction Y, and not parallel to the second direction X). The fourth inclined trace 24 is connected to the second end 121. The second inclined trace 22 is symmetric to the fourth inclined trace 24 relative to a second axis A2. The second axis A2 is parallel to the second direction X.

With reference to FIG. 2, in one embodiment, the traces 2 further comprises a first transverse trace 251 and a second transverse trace 252. One end of the first transverse trace 251 is connected to the first section 11. The first transverse trace 251 extends along the first axis A1. One end of the second transverse trace 252 is connected to the second end 121. The second transverse trace 252 extends along the second axis A2.

With reference to FIG. 2, in one embodiment, the traces 2 comprises a first vertical trace 261, a second vertical trace 262, a third vertical trace 263 and a fourth vertical trace 264. The first vertical trace 261, the second vertical trace 262, the third vertical trace 263 and the fourth vertical trace 264 are parallel to the first direction Y. The first vertical trace 261 is connected to the first end 111. The second vertical trace 262 is connected to the connection portion 13. The extending direction of the first vertical trace 261 is opposite to the extending direction of the second vertical trace 262. The third vertical trace 263 is connected to the second end 121. The fourth vertical trace 264 is connected to the second end 121. The extending direction of the third vertical trace 263 is opposite to the extending direction of the fourth vertical trace 264.

With reference to FIGS. 1 and 2, in one embodiment, the traces 2 are configured in a radial manner. The light-emitting device M comprises a positioning mark K. The positioning mark K is disposed between the pair of bonding pads (P1, P2). The pair of bonding pads (P1, P2) are symmetric to an axis of symmetry A3. The axis of symmetry A3 is parallel to the first direction Y. The axis of symmetry A3 passes through the positioning mark K.

In the embodiment of the electrical module of the light-emitting device, which adopts designs such as bonding line and traces to meet the requirements of linearity and resistance of thrust. The first section of the bonding line is perpendicular to the second section thereof to improve alignment accuracy, and the traces can extend obliquely to resist thrusts in different directions. In one embodiment, the number of such traces can be up to 10 to provide sufficient resistance of thrust. Specifically, under the same or smaller bonding pad area, the bonding lines of the embodiments of the disclosure not only provide good linearity, but also provide better resistance of thrust.

In one embodiment, the quantity, position and direction of the traces can be appropriately modified, and above mentioned does not restrict the disclosure.

The light-emitting device of the embodiment of the disclosure can be incorporated in displays, keyboards or other electronic devices with light-emitting requirement.

While the disclosure has been described by way of example and in terms of the preferred embodiments, it is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electrical module, comprising:
a circuit board; and
a bonding pad disposed on the circuit board, wherein the bonding pad comprises a bonding line and a plurality of traces connected to the bonding line,
wherein the bonding line comprises a first section and a second section, the first section is connected to the second section and extends towards a first direction, the second section extends towards a second direction perpendicular to the first direction, and one of the traces extends towards a third section different from the first direction and the second direction.

2. The electrical module as claimed in claim 1, wherein the traces are configured in a radial manner.

3. The electrical module as claimed in claim 1, wherein the bonding line is L-shaped, the first section comprises a first end, the second section comprises a second end, and the first section is connected to the second section at a connection portion of the bonding line.

4. The electrical module as claimed in claim 3, wherein the traces comprise a first inclined trace extending towards a direction between the first direction and the second direction, and the first inclined trace is connected to the first end.

5. The electrical module as claimed in claim 4, wherein the traces comprise a second inclined trace extending towards a direction between the first direction and the second direction, and the second inclined trace is connected to the second end.

6. The electrical module as claimed in claim 5, wherein the traces comprise a third inclined trace extending towards a direction between the first direction and the second direction, the third inclined trace is connected to the connection portion, and the first inclined trace is symmetric to the third inclined trace relative to a first axis parallel to the second direction.

7. The electrical module as claimed in claim 6, wherein the traces comprise a fourth inclined trace extending towards a direction between the first direction and the second direction, the fourth inclined trace is connected to the second end, and the second inclined trace is symmetric to the fourth inclined trace relative to a second axis parallel to the second direction.

8. The electrical module as claimed in claim 7, wherein the traces further comprise a first transverse trace and a second transverse trace, wherein the first transverse trace is connected to the first section and extends along the first axis, and the second transverse trace is connected to the second end and extends along the second axis.

9. The electrical module as claimed in claim 8, wherein the traces comprise a first vertical trace, a second vertical trace, a third vertical trace and a fourth vertical trace, wherein the first vertical trace, the second vertical trace, the third vertical trace and the fourth vertical trace are parallel to the first direction, the first vertical trace is connected to the first end, the second vertical trace is connected to the connection portion and extends toward a direction opposite to that of the first vertical trace, the third vertical trace is connected to the second end, the fourth vertical trace is connected to the second end and extends towards a direction opposite to that of the third vertical trace.

10. A light-emitting device, comprising:
an electrical module, comprising:
a circuit board; and
a bonding pad disposed on the circuit board, wherein the bonding pad comprises:
a bonding line and a plurality of traces connected to the bonding line,
wherein the bonding line comprises a first section and a second section, the first section is connected to the second section and extends towards a first direction, the second section extends towards a second direction perpendicular to the first direction, and one of the traces extends towards a third section different from the first direction and the second direction; and
a light source element is connected to the bonding pads.

11. The light-emitting device as claimed in claim 10, wherein the traces are configured in a radial manner.

12. The light-emitting device as claimed in claim 10, further comprising a positioning mark, wherein the positioning mark is disposed between the bonding pads, the bonding pads are symmetric to an axis of symmetry, the axis of symmetry is parallel to the first direction, and the axis of symmetry passes through the positioning mark.
